(19) United States
(12) Patent Application Publication
(10) Pub. No.: US 2004/0113168 A1
(43) Pub. Date: Jun. 17, 2004

(54) Light extraction efficiency of gan based leds

(76) Inventors: Ivan Eliashevich, Maplewood, NJ (US); Michael Wang, Lake Zurich, IL (US)

Correspondence Address: Scott A McCollister, Fay Sharpe Fagan Minnich & McKee, 7th Floor, 1100 Superior Avenue, Cleveland, OH, 44114-2518, US

(21) Appl. No.: 10/399,635

(22) PCT Filed: Feb. 21, 2001
(86) PCT No.: PCT/US01/05632

(51) Int. Cl. H01L 33/00

(52) U.S. Cl. 257/99

(57) ABSTRACT

An optoelectronic device has a semiconductor structure (10) on a substrate (12). The shape of the device in plan is that of a quadrilateral having two acute included angles (α1, α2) and two obtuse included angles (α1, α2). One of the electrode-pad units (31) is located distally from the vertices of the quadrilateral. The device may have a transparent electrode (32).

### TECHNICAL FIELD

The present invention relates to optoelectronic devices such as light-emitting diodes.

### BACKGROUND ART

Light emitting diodes or “LEDs” include thin layers of semiconductor material of two opposite conductivity types, referred to as p-type and n-type. The layers are disposed in a stack, one above the other, with one or more layers of n-type material in one part of the stack and one or more layers of p-type material at the other end of the stack. For example, the various layers may be deposited in sequence on a substrate to form a wafer. The junction between the p-type and n-type material may include directly abutting p-type and n-type layers, or may include one or more intermediate layers which may be of any conductivity type or which may have no distinct conductivity type.

Electrodes are connected to the n-type and p-type layers near the top and bottom of the stack. The materials in the electrodes are selected to provide low-resistance interfaces with the semiconductor materials. The electrodes, in turn, are provided with pads suitable for connection to wires or other conductors which carry current from external sources. The pad associated with each electrode may be a part of the electrode, having the same composition and thickness of the electrode, or may be a distinct structure which differs in thickness, composition, or both from the electrode itself. The term “electrode-pad unit” is used in this disclosure to refer to the electrode and pad, regardless of whether the pad is a separate structure or merely a region of the electrode. The wafer is cut apart to form individual dies which constitute separate LEDs.

In operation, electric current passing through the diode is carried principally by electrons in the n-type layers and by electron vacancies or “holes” in the p-type layers. The electrons and holes move in opposite directions toward the junction, and recombine with one another at the junction. Energy released by electron-hole recombination is emitted as light. As used in this disclosure, the term “light” radiation includes infrared and ultraviolet wavelength range, as well as the visible range. The wavelength of the light depends on factors including the composition of the semiconductor materials and the structure of the junction.

LEDs formed from certain semiconductor materials normally use nonconductive substrates to promote proper formation of the semiconductor layers. The nonconductive substrate typically is left in place. For example, gallium nitride-based materials such as GaN, AlGaN, InGaN and AlInGaN are used to form LEDs emitting light in various wavelength ranges including blue and ultraviolet. These materials typically are grown on insulating substrates such as sapphire or alumina.

LEDs incorporating an insulating substrate must include a bottom electrode at a location on the stack above the substrate but below the junction. Typically, the upper layer or layers of the stack are removed in a region of the stack, so as to provide an upwardly-facing lower electrode surface on a layer at or near the middle of the stack in each die. This leaves a region referred to as a “mesa” projecting upwardly from the lower electrode surface and covering the remaining area of the die. The area of the die occupied by the lower electrode surface does not emit light. It is desirable to keep the horizontal extent of this inactive area as small as possible.

The top electrode typically is formed on the top surface of the stack, i.e., the top surface of the top semiconductor layer. Typically, the layers in the stack above the junction are transparent, so that light emitted at the junction can pass out of the stack through the top surface. The top electrode is arranged so that it does not block all of the emitted light. For example, an opaque top electrode may cover only a small portion of the top surface of each die. However, “current crowding” or “current bunching”, results in light emission concentrated in that area of the junction beneath the electrode, precisely where it will be most effectively blocked by the electrode. The amount of useful light reaching the outside of the die per unit of electrical current passing through the die, commonly stated as the external quantum efficiency of the die, is reduced by this phenomenon. Current crowding can also occur in the lower region, so that light emission is concentrated in the area of the junction near the lower electrode. Current crowding is a significant consideration with LEDs formed from materials having relatively high electrical resistivity, such as the gallium nitride-based materials.

To alleviate the current crowding problem, LEDs have been provided with transparent top electrodes, formed from thin layers of metals and metal compounds. A pad, which is typically opaque, occupies a small portion of the top surface. The transparent top electrode spreads the current in horizontal directions from the pad, so that current flow down through the stack is spread more evenly over the horizontal extent of the mesa.

Certain LEDs have an absorptive cavity, reducing the light extraction efficiency for the LED. The light generated by the LED must pass through absorption regions of the LED before exiting the LED and some of the light is trapped in the absorptive cavity of the LED. For example, in certain LEDs, a p-type layer overlies an n-type layer, an active layer is interposed therebetween, and these layers are disposed upon a substrate of sapphire or alumina. The LED may also be attached to surrounding structure utilizing a die-attach epoxy to form an assembly. The p-type layer, n-type layer, active layer and die-attach epoxy all absorb a large proportion of the light generated in the LED. Thus, improvements to LEDs improving the light extraction efficiency are desirable.

### DISCLOSURE OF THE INVENTION

The present invention addresses these needs.

In a first aspect of the present invention, a surface-emitting optoelectronic device comprises a semiconductor structure on a substantially planar substrate. The device has a shape, when seen in plan view in a viewing direction normal to the plane of the substrate and the shape comprises a quadrilateral with two acute included angles and two obtuse included angles. The device has a first electrode-pad unit located on the structure distally from the vertices of the shape. Preferably, the shape is substantially in the form of a parallelogram and, more preferably, the parallelogram is a rhombus. The quadrilateral shape of the device, with angles unequal to 90°, improves the light extraction efficiency for the device. Without being committed to any particular theory of operation, the device can be modeled as a wave guide and the quadrilateral shape with angles unequal to 90° comprises a wave guide structure that emits more leakage mode light and tends to be less absorbed by the device.

The acute included angles are preferably between about 25° and about 50° and the obtuse included angles are between about 130° and 155°. In certain preferred embodiments, the acute included angles are about 30° and the obtuse included angles are about 150° and in other preferred embodiments, the acute included angles are about 45° and the obtuse included angles are about 135°.

In a preferred structure, the device comprises a stacked structure, including a first region of a first conductivity type, a second region of a second conductivity type, and a light-emitting p-n junction between the regions. The stacked structure defines a lower surface and a mesa projecting upwardly from the lower surface. The mesa has a top surface and a first electrode-pad unit is disposed on the top surface. Thus, the device has a stepped structure in certain preferred embodiments, and electrode-pad units for delivering electrical power to the device.

The first electrode-pad unit on the mesa preferably has a first electrode on the top surface of the mesa and a first pad on the first electrode. The first pad overlies only a portion of the top surface of the mesa.

The first conductivity type region is preferably disposed in the mesa and defines the top surface. The first electrode comprises a transparent first electrode overlying the top surface of the mesa. The transparent electrode is in contact with the first conductivity type region at the top surface and the first pad overlies only a portion of the transparent electrode. Thus, light is emitted out of the top of the device, through the transparent electrode and the first pad, which may not be transparent, block only a small portion of the emitted light.

Preferably, the transparent electrode overlies at least a major portion of the top surface of the mesa. In overlying a major portion of the top surface, the transparent electrode addresses the current crowding problem, while still allowing light to be emitted through the transparent electrode.

The top pad preferably overlies the top surface adjacent the center of the top surface. A second electrode-pad unit is disposed on the lower surface. The second electrode-pad unit may comprise, for example, a second electrode in the form of a loop substantially surrounding the mesa. The second electrode in the form of a loop is believed to tend to spread the current over the horizontal extent of the junction.

The stacked structure may define an indentation in the mesa adjacent the periphery thereof, extending downwardly from the top surface of the mesa to the lower surface. A second pad may be disposed adjacent the indentation. In certain preferred embodiments, the indentation extends into the mesa at a corner of the top surface.

In certain embodiments, at least that portion of the first region defining the top surface of the mesa is formed from one or more gallium-nitride based semiconductors. Many other semiconductor materials may be used in the optoelectronic device, as is well known in the art. The first conductivity type for the structure is preferably p-type and the second conductivity type is preferably n-type.

The substrate is preferably at least partially transparent to light emitted by the semiconductor structure. The substrate preferably has a bottom surface, a top surface and edges extending between the top and bottom surfaces. The substrate defines the shape of the device and the semiconductor structure overlies the top surface of the substrate. The semiconductor structure preferably has a shape approximating the shape of the substrate.

The semiconductor structure preferably has a top surface remote from the substrate, an indentation extending downwardly from the top surface of the semiconductor, and a lower electrode disposed at least partially in the indentation. The semiconductor structure preferably has edges extending parallel to the edges of the substrate except at the indentation.

In another aspect of the present invention, an optoelectronic device comprises a semiconductor structure on a substantially planar substrate. The device has a shape when seen in plan view in a viewing direction normal to the plane of the substrate and the shape comprises a quadrilateral with two acute included angles and two obtuse included angles. The device has a stacked structure including a first region of a first conductivity type, a second region of a second conductivity type, and a light-emitting p-n junction between the regions. The stacked structure defines a lower surface and a mesa projecting upwardly from the lower surface. The mesa has a top surface and a transparent electrode overlying the top surface. The shape is preferably substantially in the form of a parallelogram and, more preferably, the parallelogram is a rhombus.

The acute included angles are preferably between about 25° and about 50° and the obtuse included angles are between about 130° and 155°. In certain preferred embodiments, the acute included angles are about 30° and the obtuse included angles are about 150° and in other preferred embodiments, the acute included angles are about 45° and the obtuse included angles are about 135°.

A first pad is preferably disposed on the transparent electrode and the first pad preferably overlies only a portion of the top surface of the mesa. The transparent electrode preferably overlies at least a major portion of the top surface of the mesa. In certain preferred embodiments, the first pad overlies the top surface adjacent the center of the top surface.

Preferably, the device has an electrode-pad unit on the lower surface. The electrode-pad unit on the lower surface preferably comprises a second electrode in the form of a loop substantially surrounding the mesa, in certain embodiments.

The stacked structure defines an indentation in the mesa adjacent the periphery thereof and extending downwardly from the top surface of the mesa to the lower surface. A second pad is preferably disposed adjacent the indentation.

In certain preferred embodiments, at least that portion of the first region defining the top surface of the mesa is formed from one or more gallium-nitride based semiconductors. The first conductivity type may be p-type and the second conductivity type may be n-type.

The substrate is preferably at least partially transparent to light emitted by the semiconductor structure. The substrate preferably has a bottom surface, a top surface and edges extending between the top and bottom surfaces and defining the quadrilateral shape of the device. The semiconductor structure overlies the top surface of the substrate and the semiconductor structure has a shape approximating the shape of the substrate.

In a further aspect of the present invention, a surface-emitting optoelectronic device comprises a semiconductor structure on a substantially planar substrate. The device has a shape when seen in plan view in a viewing direction normal to the plane of the substrate. The shape comprises a quadrilateral with two acute included angles of 45° and two obtuse included angles. The device includes a first contact pad located at one of the acute included angles.

In a still further aspect of the present invention, an optoelectronic device comprises a semiconductor structure on a substantially planar substrate. The device has a shape when seen in plan view in a viewing direction normal to the plane of the substrate. The shape comprises a quadrilateral with two acute included angles and two obtuse included angles. The device has a stacked structure including a first region of a first conductivity type, a second region of a second conductivity type, and a light-emitting p-n junction between the regions. The stacked structure defines a lower surface having a second electrode-pad unit and a mesa projecting upwardly from the lower surface. The mesa has a first electrode-pad unit. The first electrode-pad unit and the second electrode-pad unit are electrically connected to contacts of a base layer and the first electrode-pad unit comprises a reflective material.

The shape is preferably substantially in the form of a parallelogram and, more preferably, the parallelogram is a rhombus.

The first electrode-pad unit preferably has a first electrode on the top surface of the mesa and a first pad on the first electrode. The first pad overlies only a portion of the top surface of the mesa.

In certain preferred embodiments, the first conductivity type region is disposed in the mesa and defines the top surface and the first electrode-pad unit comprises a transparent first electrode overlying the top surface of the mesa. The transparent electrode is in contact with the first conductivity type region at the top surface and the first pad overlies only a portion of the transparent electrode. The transparent electrode preferably overlies at least a major portion of the top surface of the mesa. The first pad preferably overlies the top surface adjacent the center of the top surface. The second electrode-pad unit may comprise a second electrode in the form of a loop substantially surrounding the mesa.

In certain preferred embodiments, the stacked structure defines an indentation in the mesa adjacent the periphery thereof extending downwardly from the top surface of the mesa to the lower surface, and the second electrode-pad unit comprises a second pad disposed adjacent the indentation. The indentation may extend into the mesa at a corner of the top surface.

Preferably, at least that portion of the first region defining the top surface of the mesa is formed from one or more gallium-nitride based semiconductors. The first conductivity type may be p-type and the second conductivity type may be n-type.

The substrate is preferably at least partially transparent to light emitted by the semiconductor structure and has a bottom surface, a top surface, and edges extending between the top and bottom surfaces. The substrate preferably defines the shape of the device and the semiconductor structure overlies the top surface of the substrate. The semiconductor structure has a shape approximating the shape of the substrate.

### BRIEF DESCRIPTION OF THE DRAWINGS

These and other features, aspects, and advantages of the present invention will become better understood with regard to the following description, appended claims and accompanying drawings where:

FIG. 1 is a top plan view of an optoelectronic device in accordance with one embodiment of the invention;

FIG. 2 is a section taken along line 2-2 in FIG. 1;

FIG. 3 is a schematic illustrating a wave guide analysis of an optoelectronic device in accordance with the embodiment of FIGS. 1-2;

FIG. 4 is a schematic illustrating the dimensions of a square and a rhombus;

FIG. 5 is a top plan view of an optoelectronic device in accordance with another embodiment of the invention;

FIG. 6 is a top plan view of an LED in accordance with a further embodiment of the invention; and

FIG. 7 is a cross-sectional view of an optoelectronic device in accordance with a further embodiment of the invention.

### MODES FOR CARRYING OUT THE INVENTION

An optoelectronic device in accordance with one is embodiment of the invention includes a semiconductor structure 10 comprising a stacked structure of semiconductor layers on a substrate 12. The stacked structure includes semiconductor material of a first conductivity type in a first region 14 of the stack and is located in an upper region of the stack. Semiconductor material of a second, opposite conductivity type in a second region 16 is located in a lower portion of the stack, adjacent substrate 12. For example, the first region 14 may be formed from a p-type semiconductor whereas the second region 16 may be formed from an n-type semiconductor. Thus, the p-type semiconductor material overlies the n-type semiconductor material. In certain preferred embodiments, the semiconductor structure 10 comprises Gallium-nitride based materials such as GaN, AlGaN, InGaN, and AlIn GaN, which are used to form LEDs emitting light in various wavelength ranges including blue and ultraviolet. The fabrication processes used to form the stacked structure are well known. The materials are typically grown on an insulating substrate 12 by chemical vapor deposition (“CVD”), metal organic chemical vapor deposition (“MOCVD”), molecular beam epitaxy, and the like. However, those of ordinary skill in the art will appreciate that a number of other semiconductor materials for forming other types of optoelectronic devices, including LEDs, may be used. The insulating substrate can comprise any substrate that is not opaque to the emitted light, such as sapphire, alumina, silicon carbide, gallium nitride, or aluminum gallium nitride, for example. An optoelectronic device using semiconductor materials disposed on any at least partially transparent substrate can benefit from the invention.

The semiconductors may be III-V semiconductors, i.e., materials according to the stoichiometric formula Alₐ In_{b} Ga_{c} Nₓ As_{y} P_{z} where (a+b+c) is about 1 and (x+y+z) is also about 1. Most typically, the semiconductor materials are nitride semiconductors, i.e., III-V semiconductors in which x is 0.5 or more, most typically about 0.8 or more. Most commonly, the semiconductor materials are pure nitride semiconductors, i.e., nitride semiconductors in which x is about 1.0. The term “gallium nitride based semiconductor” as used herein refers to a nitride based semiconductor including gallium. The p-type and n-type conductivity may be imparted by conventional dopants and may also result from the inherent conductivity type of the particular semiconductor material. For example, gallium nitride based semiconductors typically are inherently n-type even when undoped. N-type nitride semiconductors may include conventional electron donor dopants such as Si, Ge, S, and O, whereas p-type nitride semiconductors may include conventional electron acceptor dopants such as Mg and Zn.

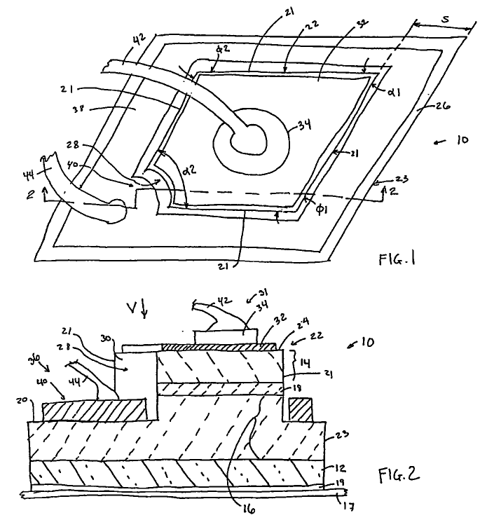

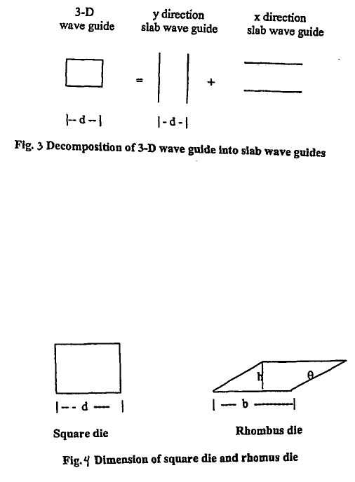

The stacked structure 10 of the embodiment shown in FIGS. 1 and 2 comprises an LED including a junction 18 between the first and second regions. The junction is shown schematically in FIG. 2 as a discrete layer interposed between regions 14 and 16. In practice, the junction may comprise the border between directly abutting p-type and n-type layers, or one or more intermediate layers. The intermediate layers may have any conductivity or no conductivity type. Alternatively, the junction may include additional structures in between regions 14 and 16 or in an intermediate region. Thus, the junction may be a simple homojunction; a single heterojunction, a double heterojunction, a single quantum well, a multiple quantum well or any other type of junction structure. A person of ordinary skill in the art will appreciate that the semiconductor structure may incorporate various layers of semiconductor materials, as well as other structures used in the optoelectronic arts.

Also, each of regions 14 and 16 can include any number of layers. Merely by way of example, the second lower region 16 may incorporate a “buffer layer” at the interface with substrate 12, whereas the first region 14 may incorporate a highly doped contact layer at the top of the stack to aid in establishing ohmic contact with a top electrode discussed below. The first region 14 typically is transparent to light at the wavelength which will be emitted by the LED in service. That is, the upper region is formed entirely or principally from materials having a band gap greater than the energy of the photons which will be emitted at the junction. The structure and composition of the various layers incorporated in the stack and the sequence of layers in the stack may be selected according to known principles and techniques to provide the desired emission characteristics.

The second region 16 defines a second region contact surface 20. Surface 20 faces upwardly, away from substrate 12 and second region 16 has edges 23 that extend downwardly from the surface 20. The stacked structure also defines a mesa 22, projecting upwardly from the second region contact surface 20. The mesa 22 has vertically extending walls 21 that are generally parallel with the second region 16 edges 23. The junction 18 and the first region 14 are disposed within the upwardly projecting mesa 22. The first region 14 defines the top surface 24 of the mesa. Typically, the second region contact surface 20 and mesa 22 are formed by an etching process after the layers which form the stacked structure have been deposited on the substrate 12. Thus, the semiconductor materials are deposited on the substrate 12, forming a stack of the semiconductor materials which will form the structure 12. The layers of semiconductor material which form the first region 14, junction 18, and a portion of the layer or layers of semiconductor material which form the second region 16 are removed by selectively etching those areas which are to form the second region contact surface 20. The regions in those areas which are to form the mesa 22 are protected by a mask so as to form the upwardly projecting mesa 22. Such an etching process may use, for example, conventional photolithographic masking techniques. Alternatively, the second region contact surface 20 and mesa 22 are formed by selective deposition. In a selective deposition process, semiconductor material for the second region 16 is deposited. The areas of the die which are to form the second region contact surface 20 are then covered with a masking material or otherwise protected from the deposition process, so that the uppermost layers in the stack are not formed in these areas.

The edges of the substrate 12, walls 21 of mesa 22, and edges 23 of second region 16 of the semiconductor structure 10 need not be perpendicular to the plane of the substrate; they may be curved or inclined.

The structure 10 is typically attached to a base layer 17 utilizing die-attach epoxy 19, as is known in the art, to form an assembly. For example, die attach epoxy may be used to attach structure 10 to a reflector.

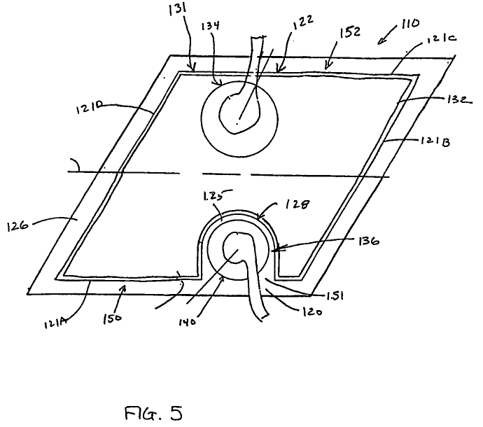

A plan view of the structure 10 is shown in FIG. 1, showing the structure 10 viewed in a viewing direction perpendicular to the plane of the substrate 12. The viewing direction “V” is shown in the cross-sectional view of FIG. 2. The structure 10 has an overall shape in plan of a quadrilateral with included angles other than 90°. In other words, the structure 10 has the shape in plan of a quadrilateral having two acute included angles and two obtuse included angles. Preferably, the shape of the structure 10 in plan is that of a rhombus or other parallelogram. The rhombus-shaped structure 10 has a width “b” and a length “h”, as shown in FIG. 4.

The shape of the mesa, when viewed in plan, is formed utilizing the mask and photolithography or selective deposition discussed above. The overall shape of the structure 10 is preferably formed utilizing a laser after forming the electrode-pad units discussed below.

It should be appreciated that the figures are not drawn to scale. In particular, the thicknesses of the various layers have been greatly exaggerated for clarity of illustration. Typically, the entire stack including mesa 22 is on the order of five microns thick. The horizontal dimensions, such as the overall width b and length h are on the order of a few hundred microns as, for example, about 200-300 microns.

The shape of mesa 22, when seen in top plan view as in FIG. 1, is substantially similar to the overall shape of the structure 10. Thus, the second region 16 preferably has the shape of a rhombus when viewed in plan and mesa 22 preferably has the shape of a rhombus when viewed in plan. The vertically extensive walls 21 of mesa 22 extend generally parallel to edges 23 of the second region 16. Preferably, the lower contact surface 20 includes strip-like regions 26 extending around the perimeter of the mesa 22. For example, in structures having the shape of a rhombus in plan, mesa 22 has four walls 21 and second region 16 has four edges 23. Each of the walls 21 are parallel with one of the edges 23 so that the second region contact surface 20 extends around the perimeter of the mesa 22.

The rhombus-shaped mesa has a first acute included angle α1, a second acute included angle α2, a first obtuse included angle φ1, and a second obtuse included angle φ2, at the vertices of the rhombus. The width S of the strip is preferably as small as possible while still providing room to accommodate the lower electrode-pad unit discussed below. Typically, the width S of the strip is on the order of 10-50 microns.

The mesa 22 has an indentation 28 at one of the corners defined by the walls 21. The indentation extends downwardly from the top surface 24 of the mesa to the lower region contact surface 20 and extends inwardly from the walls 21, so that the indentation 28 has a vertically extensive wall 30 that joins with the walls 21 defining the mesa 22. Thus, the second region contact surface 20 includes a portion defining the floor of indentation 28. This portion merges with the strips 26 (FIG. 1) of the lower region contact surface 20. Indentation 28, when seen in top plan view, is generally in the form of a quarter-circle, having a radius of, for example, about 100 microns or so. The indentation 28 is formed when the mesa 22 is formed. For example, the mask used in the deposition process discussed above may be formed in the shape of the indentation 28, or the mask in the etching process may be formed so as to outline the shape of the invention 28.

A first electrode-pad unit 31 preferably includes a transparent first electrode 32 covering substantially the entire top surface 24 of the mesa 12. The first electrode 32 is formed from a material which will provide a low resistance, desirably ohmic contact, with the semiconductor material of the first region 14 defining the upper surface 24 of the mesa. The composition and thickness of the transparent electrode are selected to provide substantial transparency to light at the wavelength which will be emitted by the LED in service. Suitable materials, thicknesses and processing techniques for forming transparent electrodes to be used with particular semiconductor materials are well known. Merely by way of example, one suitable top electrode for use where the upper surface 24 is defined by p-type gallium nitride can be formed by applying a layer of nickel, typically about 10 to about 500 Å thick and a layer of gold, typically about 10 to about 500 Å thick, onto the top surface and annealing the contact in an oxidizing atmosphere at an elevated temperature as, for example, about 300-900° C. so as to oxidize the nickel. The layers of metal are applied using electron beam deposition, sputter deposition, plating, or other known methods. Preferably, the metals for electrode 32 are deposited so that edges of the electrode are spaced from the walls 21 of the mesa 22 using, for example, a photolithographic mask. Depositing the metal in this manner can avoid depositing metal overlapping with the electrodes on surface 20 which will be discussed below.

The top electrode-pad unit also preferably includes a pad 34 formed on the top surface of first electrode 32 at or near the horizontal center of the mesa, i.e., near the center of the top surface 24 of the mesa 22. Pad 34 is formed from appropriate materials to provide a terminal which can be connected to an external lead in service as, for example, by wire bonding the lead to the pad. The materials of the pad should also be compatible with the materials in electrode 32. Merely by way of example, pad 34 may include a layer of titanium overlying the transparent electrode 32; a layer of platinum overlying the titanium layer and a layer of gold overlying the platinum layer. The exposed layer of gold provides a suitable surface for wire bonding. The pad 34 typically has a diameter of about 100-120 microns. Desirably, this pad is as small as possible consistent with the requirements of the bonding operation used to connect the pad to external circuitry. Thus, the top pad desirably occupies less than about 10 percent of the mesa's top surface.

A second electrode-pad unit 36 is provided on the second region contact surface 20. This electrode-pad unit preferably includes an electrode having a partially circular pad region 40 extending into indentation 28 of the mesa and elongated, strip-like portions 38 extending from the pad region 40 along the strip-like regions 26 of the second region contact surface 20. Preferably, the elongated strip-like portions 38 extend entirely around mesa 22. Pad region 40 may be, for example, about 100 microns wide, whereas strip portions 38 may be about 3 to about 20 microns wide. Strip portions 38 provide a second electrode in contact with the second region contact surface 20. The strip portions are formed from electrically conductive materials which make a good, desirably ohmic electrical contact with the second region contact surface 20. For example, where the second region contact surface 20 is formed by n-type gallium nitride, the strip portions 38 may be formed from layers of aluminum and titanium which are annealed at an elevated temperature. Pad region 40 preferably comprises electrically conductive material so as to serve as part of the electrode and may include the same layers of aluminum and titanium. The pad region 40 also preferably includes layers adapted for bonding to external leads or other structures. For example, the pad region 40 may include a layer of platinum over the titanium and aluminum layers and a layer of gold over the platinum layer. The gold layer provides a good bonding surface. In a particularly preferred arrangement for use with gallium nitride-based semiconductors, the entire lower electrode-pad unit, including pad region 40 and strip-like electrode portions 38 is formed from layers of aluminum, titanium, platinum and gold, deposited in that order and then annealed.

In certain preferred embodiments, the pad region 40 is located at one of the acute included angles of the quadrilateral-shaped structure 10. For example, and as shown in FIG. 1, the pad region 40 is located outside the vertice having the second acute included angle α2 of mesa 22. By contrast, the first pad 34 is preferably located distally from the pad region 40. In certain preferred embodiments, the first pad 34 is located distally from the vertices having included angles α1, α2, φ1, and φ2 of the mesa 22. The pad region 40 and first pad 34 may be located in any of the vertices of the quadrilateral-shaped structure 10. The first electrode 32 may comprise a small pad located in one of the vertices of the quadrilateral. Preferably, the electrode 32 comprises a transparent electrode and, more preferably, a transparent, current-spreading electrode taking up a large portion of the top surface 24 of mesa 22. Preferably, the first pad 34 comprises a small pad located on a transparent, current-spreading electrode, at or near the center of the surface 24 of the mesa 22.

Preferably, the semiconductor materials for a plurality of devices are deposited to form a wafer. Mesas and electrode-pad units are formed for each device and then the wafer is severed into individual devices. In severing the wafer into individual devices, the overall shape of the structure is formed. Preferably, the wafer is cut utilizing a laser. Alternatively, mechanical scribing is used. In mechanical scribing, small scratches are made on the semiconductor materials with a diamond-tipped tool. Then, the semiconductor material is broken along the lines formed by the scratches. The wafer is severed so as to form the quadrilateral shape in plan.

The entire stacked structure 10, apart from pad region 40 and first pad 34 may be covered by a transparent, electrically insulating material such as a silicon oxide (not shown) to protect the device.

In use, the first pad 34 and pad region 40 are connected by wire bonds 42 and 44 to an external electrical power source. Current flows between pads 34 and 46 through the electrodes and through the stacked structure, so that light is emitted at junction 18. The light is emitted out of the structure, through the transparent first electrode 32. Thus, the LED shown in FIGS. 1 and 2 is a surface-emitting LED. Other types of optoelectronic devices may make use of the features of the present invention.

The transparent electrode 32 and the strip-like regions 38 of the electrode surrounding the mesa 22 promote current spreading through the horizontal extent of the mesa and uniform distribution of the current through the horizontal extent of junction 18. Without committing to a particular theory of operation, the first electrode 32 reduces the resistance to current flow in horizontal directions of the structure disposed above the junction. Without committing to a theory of operation, the electrode on second region contact surface 20 tends to equalize potential around the periphery of the mesa in the lower region of the structure 12, thus further tending to spread the current over the horizontal extent of the junction. Moreover, the electrode contacts the region 20 over a large perimeter and it is believed that the lower electrode-pad unit 36 tends to reduce any tendency to current crowding in the lower region. Regardless of the mechanism of operation, this structure tends to provide efficient operation. It would appear that providing the strip-like regions 26 of the second contact surface 20 extending around the perimeter of the mesa 22 will reduce the area occupied by the mesa. However, such strip-like regions 26 can be at least partially accommodated in a part of the area of the structure which otherwise would be wasted. The semiconductor materials are preferably formed as a wafer and a plurality of structures 10 for forming a plurality of LEDs are formed from the wafer. In many cases, trenches are etched into the wafer from the top surface to facilitate separation of the individual structures from one another. The strip-like regions 26 can be at least partially provided in the area occupied by these trenches.

Quadrilateral-shaped structures having included angles other than 90° improve the light extraction efficiency of LEDs. For example, a structure 10 of gallium-nitride based materials has an absorptive cavity consisting of two zones of the LED. The first zone is comprised of the first region 14, the second region 16, and the junction 18. The second zone is the highly absorptive die-attach epoxy 19. These zones, together, lower the light extraction efficiency of the LED.

A wave guide model of the structure discussed above in connection with FIGS. 1 and 2 LED shows that about 70% of light in the wave guide, consisting of the substrate 12 and its surrounding medium, is of the “guided modes” variety. Without committing to any particular theory of operation, the guided mode light suffers the most absorption because, the light needs to pass through either of the two above-mentioned absorption regions before the light can come out of the LED. The guided modes experience more absorption than leakage modes do because most of leakage light will come out of the side walls of the die without entering the absorption region which are located at top and bottom of LED die. One technique to overcome this drawback is to put a reflector at the bottom of the substrate 12 and the guided mode light no longer passes through the highly absorptive die-attach epoxy 19. However, some of the reflected light is believed to re-enter the other high absorption region of LED consisting of the active region of the LED and the transparent contact, resulting in some of the light reflected by the bottom reflector becoming trapped in the absorptive cavity.

Without committing to any particular theory of operation, it is believed that structures having a quadrilateral shape with included angles other than 90° alter the wave guide structure for the LED. As a result, more light is of the leakage mode instead of the guided mode variety. It is believed that the leakage mode light is mainly confined in the substrate 12, and come out from the side walls of the substrate 12. Thus, the reduction in the light intensity in the absorption regions of the LED is believed to be avoided.

For example, a structure 10 including a junction having layers of AlGaN and InGaN has absorption regions. InGaN has a strong absorption at blue wavelengths, and both the p-type and n-type gallium-nitride based layers also absorb blue light, though, with relatively lower absorption coefficient when compared to the InGaN layer. The transparent electrode absorbs about 10% of the light passing through it. All of these above layers form the absorption region of blue light. In addition, at the bottom of the substrate of the LED die, the die-attach epoxy absorbs light. So, the structure can be modeled as a highly absorptive 3-D wave guide. Light passing through such a wave guide parallel or perpendicular to the plane of the substrate 12 can be in a guided mode or a leakage mode.

Without committing to a particular theory or operation, it is believed that a structure having a quadrilateral shape in plan, with included angles other than 90°, changes the wave guide structure, increasing the amount of leakage mode light. It is believed that more light will come out of the side walls of the structure, which significantly reduces the light absorption.

The three-dimensional wave guide model can be decomposed into two infinite slab wave guides in the x and y directions, as shown in FIG. 3. For example, a slab wave guide theory was used to model the 3-D wave guide for the structure shown in FIGS. 1 and 2, without applying complicated 3-D wave guide theory. It has been shown that the number of guided modes the slab wave guide can support is proportional to d, the confined dimension of the wave guide, shown on a square in FIG. 4.

For a structure having the same area, the confined dimension of a rhombus structure is h. For the dimension h, h=d (sin) 0.5. The rhombus structure has a height h which is smaller than the width d of a square and the reduced height for the wave guide decreases the number of guided modes, and consequently, increases the number of leakage modes. For the same area, a rhombus structure has a total side wall area that is greater than the side wall area of a square structure. The total side wall area for a rhombus structure is 1/(sin) 0.5 times that of square structure. As a result, more light can come out of the side walls of a rhombus-shaped structure.

Numerical simulation results utilizing the above-discussed theory are shown in Table 1. Table 1 shows that light extraction efficiency can be improved by about ˜20% for a rhombus structure having a thickness equal to 125 microns and with angles α1 and α2=45°. By comparison, a hexagonal structure results in only a 9% improvement. In this simulation, the total area of the structure was kept unchanged.

The improvement is even more dramatic for a thicker structure, up to 33% for 425 micron thick rhombus structure with angles α1 and α2=45°. The efficiency improves with the thickness of the structure and the thickness of the substrate.

TABLE 1
Total extraction efficiency (TEE) for
varying die shapes (Trace Pro simulation)

| | TEE for | Difference | TEE for | Difference |
|---|---|---|---|---|
| | 125 micron | with square | 425 micron | with square |
| Die Shape | thick die | die | thick die | die |
| Circular | 8.1% | −4.7% | | |
| Square | 8.5% | 0% | 9% | 0% |
| Hexagon | 9.3% | 9.4% | | |
| Quadrilater | 10.3% | 21.2% | 12% | 33.3% |
| al (45/135) | | | | |
| Quadrilater | 10.3% | 21.2% | | |
| al (30/150) | | | | |

The shapes discussed above, such as “rhombus-shaped” represent the shape of the LED when seen in plan view, looking at the die in the viewing direction V normal to the plane of the substrate 12. As noted above in Table I, a hexagon shape provides some improvement over a square shape. Other polygonal shapes having included angles unequal to 90° can be employed as, for example, triangular and pentagonal shapes, but the parallelogram and, specifically, rhombus, are preferred.

As disclosed in the copending, commonly assigned United States Patent Application entitled CONTACT CONFIGURATIONS FOR OPTOELECTRONIC DEVICES, U.S. patent application Ser. No. 09/692,953, fled Oct. 20, 2000, the disclosure of which is hereby incorporated by reference herein, the strip-like regions of the second region contact surface 20 may entirely or substantially surround the mesa as discussed above in connection with FIGS. 1 and 2.

The electrodes may be located at locations other than the vertices of the quadrilateral shape. For example, in the embodiment shown in FIG. 5, a structure 110 in accordance with a further embodiment of the invention includes a stacked structure similar to that discussed above with reference to FIGS. 1 and 2. Here again, the second region of the stacked structure defines an upwardly facing second contact surface 120. A mesa 122 that projects upwardly from the surface 120. Mesa 122 has four walls 121A, 121B, 121C, and 121D. The mesa has an indentation 128 on one of the walls 121A of the mesa referred to herein as the “near edge” 150 extending in a first direction (from left to right as seen in FIG. 5). The second region contact surface 120 includes a portion 151 defining the lower surface or floor of indentation 128. In this embodiment, however, the second electrode-pad unit 136 includes only an electrically-conductive pad 140. The lower surface of the pad 140 constitutes the electrode that comprises a low-resistance, desirably ohmic contact with the semiconductor material of the structure 110. Stated another way, the electrode-pad unit 136 does not include the strip-like electrode portions 38 discussed above with reference to FIG. 1. Although the stack has strip-like regions 126 entirely surrounding the mesa and merging with the floor of indentation 128, these strip-like regions 126 do not carry an electrode for the lower electrode-pad unit 136.

The first electrode-pad unit 31 includes a transparent first electrode 132 and first pad 134 similar to the corresponding elements discussed above with reference to FIGS. 1 and 2. In this embodiment, however, the first pad 134 is disposed adjacent a wall 121C of the mesa, referred to herein as the “far edge” 152, extending parallel to the near edge 150 on the opposite side of the mesa. Thus, the first pad 134 is disposed remote from the second pad 140. Desirably, the indentation 128 and second pad 140 are disposed adjacent the center of the near edge 150, whereas the first pad 134 is disposed adjacent the center of the far edge 152. Because the strip-like electrode portions 38 (FIG. 1) are not employed, the second region contact surface 120 of FIG. 5 may include only very narrow strip-like regions 126 surrounding the mesa. In a further variant, the strip-like regions 126 of surface 120 may be omitted, so that the mesa extends to the outer periphery of the structure except at indentation 128 and the second region contact surface 120 consists only of the area 125 defining the floor of the indentation.

In the arrangements discussed above with reference to FIG. 5, relatively little of the area of the structure 110 is occupied by the second region contact surface, leaving a greater proportion of the structure area for the mesa. This, in turn, provides a larger active area, i.e., a junction occupying a greater proportion of the area of the structure. Such a design can be used advantageously to reduce the current density in the junction.

In a further variant, a structure as discussed above with reference to FIG. 5 can be provided with strip-like electrode regions encircling the mesa on strip-like regions 121, as discussed above with reference to FIG. 1.

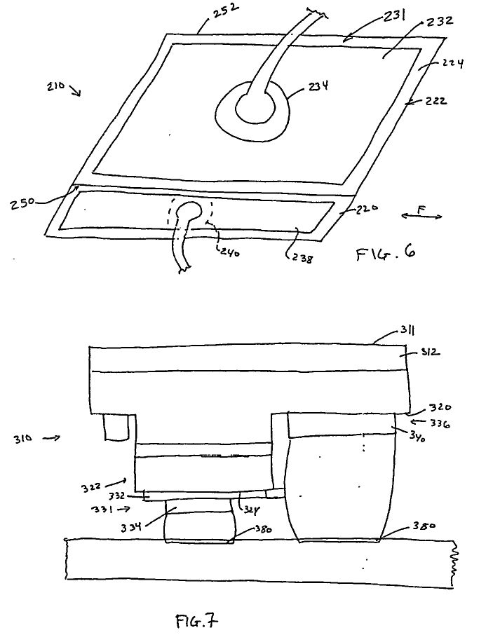

A structure 210 according to yet another embodiment of the invention includes a second contact surface 220 in the form of a ledge 253 extending along one edge of the structures (FIG. 6). The mesa 222 may occupy substantially all of the remaining die area. The second electrode-pad unit 236 includes an elongated strip-like electrode extending adjacent to and parallel to a near edge 250 of the mesa. The near edge 250 and the elongated strip-like electrode 238 extend in a first horizontal direction F, to the left and right as seen in FIG. 6. A region of this strip-like electrode serves as a pad 240. The pad may or may not be physically distinguishable from the remainder of the electrode 238. That is, the pad may or may not include thicker layers or additional layers of a metallic material. The pad 240 may be disposed at any point along the length of electrode 238, but typically it is adjacent the center of the elongated electrode and hence adjacent the center of the near edge 250. The first electrode-pad unit 231 includes a first pad 234 and transparent top electrode 232 similar to the corresponding elements discussed above. The first pad 234 is disposed remote from the near edge 250 and remote from the elongated electrode 238. Preferably, the first pad is disposed adjacent a far edge 252 of the mesa and desirably adjacent the center of the far edge. Stated another way, the first pad is aligned, in the first horizontal direction F, with the center of the elongated electrode 238. The first pad covers only a small portion of the top surface 224 of the mesa. In particular, the dimension of the first pad in the first direction F is substantially smaller than the length of second electrode 238. Structures according to this embodiment can provide relatively low contact resistance and good current spreading. In a further variant, the second contact surface may extend along edges of the mesa other than near edge 250. Thus, the second electrode contact surface may merge with strip-like regions surrounding the mesa. For example, where a wafer is etched to form semiconductor structures, from the top and along all edges of the structure, to facilitate separation of the individual structures from the wafer, the second contact surface may include strip-like regions (not shown) extending from ledge 253 entirely around the mesa. However, the second electrode need not extend onto these strip-like regions, and hence these regions may be narrower than the strip-like regions used in the embodiment of FIGS. 1-2.

A structure in accordance with the present invention may also include non-transparent electrodes. One example of a structure utilizing a non-transparent electrode is shown in FIG. 7. The structure 310 has a substantially transparent back face 311 through which light will be directed. For example, the transparent back face may comprise a sapphire substrate 312. The structure 310 is a semiconductor structure comprising a stacked structure of p-type, n-type and other semiconductor materials for generating light, as discussed above. The structure 310 has a mesa 322 protruding from the structure and a second region contact surface 320. A first electrode-pad unit 331 is mounted on the mesa 322 and has a first electrode 332 and a first pad 334. A second electrode-pad unit 336 is mounted on the second region contact surface 320 and has a second pad 340. The first pad 334 and second pad 340 are connected to contacts 380 on a base layer 317. The structure 310 may be formed as discussed above in connection with FIG. 1. Structure 310 is bonded to the contacts 380 of base layer 317 by, for example, disposing a bonding material between each of the pads 334 and 340 and contacts 380. Contacts 180 are also connected to an electrical power source. Thus, light generated by this device is directed out the back face 311 and a transparent electrode for first electrode 332 is not necessary. The metal which is deposited on the structure 310 to form electrode 332 need-not be selected so as to form a transparent electrode upon subsequent annealing. The annealing step may or may not be performed depending on what is required to provide ohmic contacts.

Preferably, the first electrode 332 comprises a reflective electrode. The reflective electrode may be formed as follows. After the structure 310 having the mesa 322 has been formed, the area for the first electrode 332 is defined using a photolithographic mask on the top surface 324 of the mesa 322. Nickel is deposited on the top surface 324 of the mesa 322. Gold is then deposited on the layer of nickel. The metals may be deposited utilizing electron beam deposition, sputter deposition, plating, or other known methods. The foregoing layers of metal are then oxidized so that they become transparent. A layer of reflective metal, such as gold, is then deposited on the oxidized metal. The layer of reflective metal should be thick enough to reflect the light generated by the LED through the back surface 311. For example, where gold is utilized as the reflective metal, 0.2 microns of gold would be reflective. In other embodiments, the layer of reflective metal may comprise titanium.

Thus, the layer of reflective metal may be deposited on the first electrode 332. In other embodiments, the first electrode 332 may be comprised of one or more layers of reflective metal.

The reflective electrode 332 reflects light for improved light extraction through the substrate 312. In preferred embodiments, the layer of reflective metal deposited is thick enough so that it can be used to bond the electrode 332 to the contact 380.

The transparent top electrode can be omitted in some cases so that the top electrode-pad unit consists only of a pad and an electrode in the area occupied by the pad. This approach can be used, for example, where the first or upper region has relatively low resistance to current flow in the horizontal direction as, for example, where the first or upper region includes a thick layer of semiconductor material. More typically, however, at least in the case of LED's formed from nitride semiconductors such as GaN, the cost and difficulties encountered in growing such a layer to the requisite thickness with good crystal quality outweigh the cost and light transmission efficiency losses associated with the transparent top electrode.

Although the preferred embodiments have been described above with reference to particular semiconductor materials, it should be appreciated that the invention can be applied with dies formed from semiconductor materials other than gallium nitride based semiconductors as well. Also, the conductivity types can be reversed, so that in some cases the first or upper region can be formed from n-type semiconductor material whereas the second or lower region may be formed from p-type semiconductor material. In addition, one or both of the electrode-pad units may be located in the obtuse included angles of the quadrilateral-shaped structure.

As these and other variations and combinations of the features discussed above can be utilized without departing from the present invention, the foregoing description of the preferred embodiments should be taken by way of illustration rather than by way of limitation of the invention as defined by the claims.

We claim:

1. A surface-emitting optoelectronic device comprising a semiconductor structure on a substantially planar substrate, said device having a shape, when seen in plan view in a viewing direction normal to the plane of the substrate, said shape comprising a quadrilateral with two acute included angles and two obtuse included angles, said device having a first electrode-pad unit located on said structure distally from the vertices of said shape.

2. The device of claim 1, wherein said shape is substantially in the form of a parallelogram.

3. The device of claim 2, wherein said parallelogram is a rhombus.

4. The device of claim 2, wherein said acute included angles are between about 25° and about 50° and said obtuse included angles are between about 130° and 155°.

5. The device of claim 4 wherein said acute included angles are about 30° and said obtuse included angles are about 150°.

6. The device of claim 4 wherein said acute included angles are about 45° and said obtuse included angles are about 135°.

7. The device of claim 2, further comprising:
(a) a stacked structure including a first region of a first conductivity type and a second region of a second conductivity type and a light-emitting p-n junction between said regions, said stacked structure defining a lower surface and mesa projecting upwardly from said lower surface, said mesa having a top surface; and
(b) a first electrode-pad unit on said top surface.

8. The device of claim 7, wherein said first electrode-pad unit has a first electrode on said top surface and a first pad on said first electrode, said first pad overlying only a portion of said top surface of said mesa.

9. The device of claim 8, wherein said first conductivity type region is disposed in said mesa and defines said top surface and said first electrode comprises a transparent first electrode overlying the top surface of said mesa, said transparent electrode being in contact with said first conductivity type region at said top surface, said first pad overlying only a portion of said transparent electrode.

10. The device of claim 9, wherein said transparent electrode overlies at least a major portion of the top surface of said mesa.

11. The device of claim 10, wherein said first pad overlies said top surface adjacent the center of said top surface.

12. The device of claim 10, further comprising a second electrode-pad unit on said lower surface.

13. The device of claim 12, wherein said second electrode-pad unit comprises a second electrode in the form of a loop substantially surrounding said mesa.

14. The device of claim 8, wherein said stacked structure defines an indentation in said mesa adjacent the periphery thereof extending downwardly from the top surface of said mesa to said lower surface, and further comprising a second pad disposed adjacent said indentation.

15. The device of claim 14, wherein said indentation extends into said mesa at a corner of said top surface.

16. The device of claim 8, wherein at least that portion of said first region defining said top surface of said mesa is formed from one or more gallium-nitride based semiconductors.

17. The device of claim 8, wherein said first conductivity type is p-type and said second conductivity type is n-type.

18. The device of claim 8, wherein said substrate is at least partially transparent to light emitted by said semiconductor structure, said substrate having a bottom surface, a top surface and edges extending between said top and bottom surfaces and defining the shape of the device, said semiconductor structure overlying said top surface of said substrate, said semiconductor structure having a shape approximating the shape of the substrate.

19. The device of claim 1, wherein said semiconductor structure has a top surface remote from said substrate, an indentation extending downwardly from the top surface of the semiconductor, and a lower electrode disposed at least partially in said indentation, said semiconductor structure having edges extending parallel to the edges of said substrate except at said indentation.

20. An optoelectronic device comprising a semiconductor structure on a substantially planar substrate, said device having a shape, when seen in plan view in a viewing direction normal to the plane of the substrate, said shape comprising a quadrilateral with two acute included angles and two obtuse included angles, said device having a stacked structure including a first region of a first conductivity type, a second region of a second conductivity type, and a light-emitting p-n junction between said regions, said stacked structure defining a lower surface and a mesa projecting upwardly from said lower surface, said mesa having a top surface and a transparent electrode overlying said top surface.

21. The device of claim 20, wherein said shape is substantially in the form of a parallelogram.

22. The device of claim 21, wherein said parallelogram is a rhombus.

23. The device of claim 21, wherein said acute included angles are between about 25° and about 50° and said obtuse included angles are between about 130° and 155°.

24. The device of claim 23, wherein said acute included angles are about 30° and said obtuse included angles are about 150°.

25. The device of claim 23, wherein said acute included angles are about 45° and said obtuse included angles are about 135°.

26. The device of claim 21, further comprising a first pad on said transparent electrode, said first pad overlying only a portion of said top surface of said mesa.

27. The device of claim 26, wherein said transparent electrode overlies at least a major portion of the top surface of said mesa.

28. The device of claim 27, wherein said first pad overlies said top surface adjacent the center of said top surface.

29. The device of claim 21, further comprising an electrode-pad unit on said lower surface.

30. The device of claim 29, wherein said second electrode-pad unit comprises a second electrode in the form of a loop substantially surrounding said mesa.

31. The device of claim 30, wherein said stacked structure defines an indentation in said mesa adjacent the periphery thereof extending downwardly from the top surface of said mesa to said lower surface, and further comprising a pad disposed adjacent said indentation.

32. The device of claim 21, wherein at least that portion of said first region defining said top surface of said mesa is formed from one or more gallium-nitride based semiconductors.

33. The device of claim 32, wherein said first conductivity type is p-type and said second conductivity type is n-type.

34. The device of claim 21, wherein said substrate is at least partially transparent to light emitted by said semiconductor structure, said substrate having a bottom surface, a top surface and edges extending between said top and bottom surfaces and defining the shape of the device, said semiconductor structure overlying said top surface of said substrate, said semiconductor structure having a shape approximating the shape of the substrate.

35. A surface-emitting optoelectronic device comprising a semiconductor structure on a substantially planar substrate, said device having a shape, when seen in plan view in a viewing direction normal to the plane of the substrate, said shape comprising a quadrilateral with two acute included angles of 45° and two obtuse included angles, said device including a first contact pad located at one of said acute included angles.

36. An optoelectronic device comprising a semiconductor structure on a substantially planar substrate, said device having a shape when seen in plan view in a viewing direction normal to the plane of the substrate, said shape comprising a quadrilateral with two acute included angles and two obtuse included angles, said device having a stacked structure including a first region of a first conductivity type, a second region of a second conductivity type, and a light-emitting p-n junction between said regions, said stacked structure defining a lower surface having a second electrode-pad unit and a mesa projecting upwardly from said lower surface, said mesa having a first electrode-pad unit, said first electrode-pad unit and said second electrode-pad unit being electrically connected to contacts of a base layer, said first electrode-pad unit comprising a reflective material.

37. The device of claim 36, wherein said shape is substantially in the form of a parallelogram.

38. The device of claim 37, wherein said parallelogram is a rhombus.

39. The device of claim 37, wherein said first electrode-pad unit has a first electrode on said top surface and a first pad on said first electrode, said first pad overlying only a portion of said top surface of said mesa.

40. The device of claim 37, wherein said first conductivity type region is disposed in said mesa and defines said top surface and said first electrode-pad unit comprises a transparent first electrode overlying the top surface of said mesa, said transparent electrode being in contact with said first conductivity type region at said top surface, said first pad overlying only a portion of said transparent electrode.

41. The device of claim 40, wherein said transparent electrode overlies at least a major portion of the top surface of said mesa.

42. The device of claim 41, wherein said first pad overlies said top surface adjacent the center of said top surface.

43. The device of claim 37, wherein said second electrode-pad unit comprises a second electrode in the form of a loop substantially surrounding said mesa.

44. The device of claim 37, wherein said stacked structure defines an indentation in said mesa adjacent the periphery thereof extending downwardly from the top surface of said mesa to said lower surface, and said second electrode-pad unit comprises a second pad disposed adjacent said indentation.

45. The device of claim 44, wherein said indentation extends into said mesa at a corner of said top surface.

46. The device of claim 37, wherein at least that portion of said first region defining said top surface of said mesa is formed from one or more gallium-nitride based semiconductors.

47. The device of claim 37, wherein said first conductivity type is p-type and said second conductivity type is n-type.

48. The device of claim 37, wherein said substrate is at least partially transparent to light emitted by said semiconductor structure, said substrate having a bottom surface, a top surface and edges extending between said top and bottom surfaces and defining the shape of the device, said semiconductor structure overlying said top surface of said substrate, said semiconductor structure having a shape approximating the shape of the substrate.
